(19) United States
(12) Patent Application Publication
(10) Pub. No.: US 2025/0238069 A1
(43) Pub. Date: Jul. 24, 2025

(54) POWER CONSERVING CLOCK CIRCUIT WITH FAST START-UP

(71) Applicant: Google LLC, Mountain View, CA (US)

(72) Inventors: Tong Zhang, Sunnyvale, CA (US); James Christian Salvia, Belmont, CA (US); Johan Peter Vanderhaegen, Cupertino, CA (US); Dan Shen, Laguna Niguel, CA (US)

(21) Appl. No.: 19/025,909

(22) Filed: Jan. 16, 2025

Related U.S. Application Data
(60) Provisional application No. 63/623,154, filed on Jan. 19, 2024.

(51) Int. Cl. G06F 1/324; H03L 7/08

(52) U.S. Cl. CPC G06F 1/324; H03L 7/0802; H03L 2207/10

(57) ABSTRACT

Methods, systems, and apparatus, including computer programs encoded on computer storage media, for generating a variable quality clock signal to preserve power for electronic devices. According to one aspect, there is provided a system that includes (i) a stand-by clock, configured to produce a stand-by clock signal when the system is in a low-power mode, and (ii) a primary clock, configured to produce a primary clock signal when the system is in an active mode, with the system configured to switch from the low-power mode to the active mode by providing the output of the stand-by clock as a start-up signal to the primary clock.

### CROSS-REFERENCE TO RELATED APPLICATION

This application claims priority to U.S. Provisional Application No. 63/623,154, filed on Jan. 19, 2024. The disclosure of the prior application is considered part of and is incorporated by reference in the disclosure of this application.

### BACKGROUND

This specification relates to clock circuits for electronic devices, and more particularly to power conserving clock circuits.

Electronic devices rely on oscillating clock signals to synchronize the operations of different device components. An electronic device can govern multiple components with the same clock signal by synchronizing the operations of the components to the cycles of the clock signal. Electronic devices can generate clock signals using electronic oscillators, which produce regularly oscillating electronic signals. Examples of electronic oscillators include crystal oscillators and RC circuits.

### SUMMARY

This specification describes a clock circuit that can operate in a low-power mode to conserve power and can use a particularly configured start-up signal to switch more quickly to an active mode in order to produce a higher-quality clock signal. The system includes a stand-by clock that can produce a stand-by clock signal when the system is in the low-power mode and a primary clock that can produce a primary clock signal when the system is in the active mode. Generally, the system uses the start-up signal produced by the stand-by clock to start up the primary clock and reduce a start-up time of the primary clock when the system switches from the low-power mode to the active mode. In particular, the system can use a resonant start-up signal from the stand-by clock that oscillates at a resonant frequency of the primary clock to reduce the start-up time of the primary clock.

According to one aspect, there is provided a system that includes (i) a stand-by clock, configured to produce a stand-by clock signal when the system is in a low-power mode, and (ii) a primary clock, configured to produce a primary clock signal when the system is in an active mode, with the system configured to switch from the low-power mode to the active mode by providing the output of the stand-by clock as a start-up signal to the primary clock.

Particular embodiments of the subject matter described in this specification can be implemented so as to realize one or more of the following advantages.

By utilizing a start-up signal from the stand-by clock to start up the primary clock, the described systems can significantly reduce the start-up time of the primary clock compared to the start-up time of the primary clock without the resonant start-up signal. As an example, the described systems can use the start-up signal from the stand-by clock to start-up the primary clock between 2 and 10 times more quickly. By using a resonant start-up signal from the stand-by clock that oscillates at a resonant frequency of the primary clock, the described systems can reduce the start-up time of the primary clock using less power than would otherwise be required to start the primary clock.

Applications of the described systems may require the high quality clock signal within a short amount of time. If a particular application of the clock signal requires the high quality clock signal in a shorter length of time than the start-up time of the primary clock, the clock circuit will need to consume additional power producing the high quality clock signal before the clock signal is needed by the particular application. By reducing the start-up time of the primary clock, the system can remain in the low-power mode for a larger fraction of time while still being able to switch to the active mode and provide the high quality clock signal within a length of time required by applications of the clock circuit. The described systems can, for example, remain in the low-power mode four times more often than clock circuits that do not use a resonant start-up signal for the primary clock and can consume, on average, four times less power than conventional clock circuits. The described systems can therefore provide a high quality clock signal when needed while significantly reducing average power consumption.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example clock system for an electronic device operating in a low-power mode to conserve power and switching to an active mode in order to produce a higher-quality clock signal.

FIG. 2 is a block diagram for an example clock system.

FIG. 3 is a flow diagram of an example process for a clock system to transition between operating in a low-power mode to operating in an active mode.

FIG. 4 illustrates a comparison of power consumption by a conventional clock circuit and a clock circuit configured as described in this specification.

Like reference numbers and designations in the various drawings indicate like elements.

### DETAILED DESCRIPTION

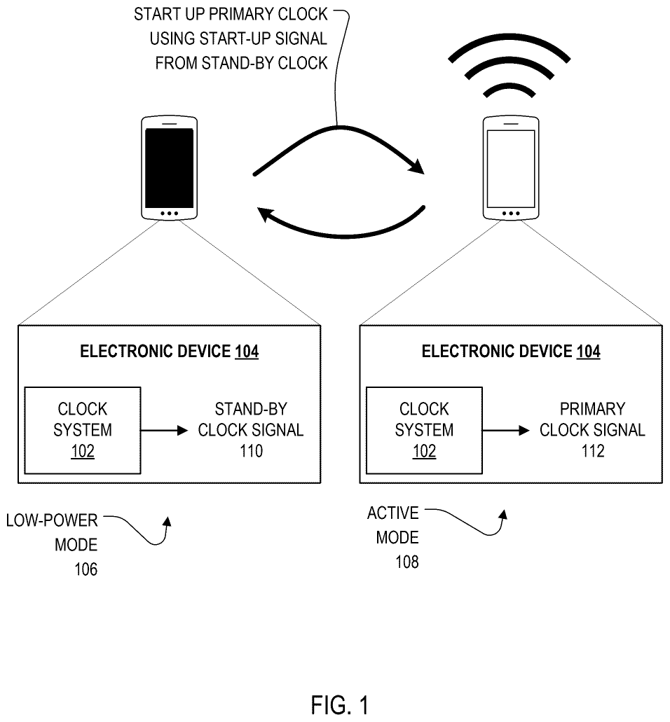

FIG. 1 illustrates an example clock system 102 for an electronic device 104 operating in a low-power mode 106 to conserve power and switching to an active mode 108 in order to produce a higher-quality clock signal using the techniques described in this specification.

For illustrative purposes, FIG. 1 depicts the clock system 102 as a component of a mobile phone. However, the system 102 can provide clock signals to any of a variety of electronic devices 104. For example, as illustrated in FIG. 1, the electronic device 104 can be a mobile phone or a component of a mobile phone that can enter a standby mode when locked. As another example, the electronic device 104 can be a laptop or a computer or a component of a laptop of computer that may enter a standby mode (e.g., a sleep mode, a hibernation mode, etc.). As another example, the electronic device 104 can be a processor or a component of a processor that may become idle.

The clock system 102 can switch from the low-power mode 106 to the active mode 108 when the electronic device 104 exits a standby mode of the device 104. For example, the electronic device 104 can be a mobile phone and the system can switch from the low-power mode 106 to the active mode 108 when a user unlocks the phone or launches an application on the mobile phone. As another example, the electronic device 104 can be a laptop, and the system can switch from the low-power mode 106 to the active mode 108 when a user wakes the laptop or launches an application on the laptop. As another example, the electronic device 104 can be a processor and the system can switch from the low-power 106 mode to the active mode 108 when the processor needs to perform computations.

The clock system 102 can use a stand-by clock to generate a lower quality stand-by clock signal 110 for the device 104 when the system 102 is in the low-power mode 106. The system 102 can use a primary clock to generate a higher quality primary clock signal 112 for the device 104 when the system is in the active mode 108. The power required by the stand-by clock to produce the stand-by clock signal 110 can be less than the power required by the primary clock to produce the primary clock signal 112. In particular, the stand-by clock can require less power than the primary clock by producing a lower quality clock signal than the primary clock, e.g., by producing a clock signal at a lower frequency than the primary clock, with more lenient accuracy tolerances than the primary clock, with less noise filtering than the primary clock, and so on.

The electronic device 104 may not always require the high quality primary clock signal 112 and may often only require the lower quality stand-by clock signal 110. To reduce power consumption, the clock system 102 can therefore enter the low-power mode 106 and output the stand-by clock signal 110 when the electronic device does not require the high quality primary clock signal 112.

In general, the primary clock has a certain start-up time between starting and being able to output the primary clock signal 112 with certain required properties such as a certain voltage accuracy, a certain timing accuracy, a certain noise level, a particular duty cycle, and so on (e.g., as required by a specification of the electronic device 104). For many applications, the start-up time of the primary clock limits how often the clock circuit 102 can operate in the low-power mode.

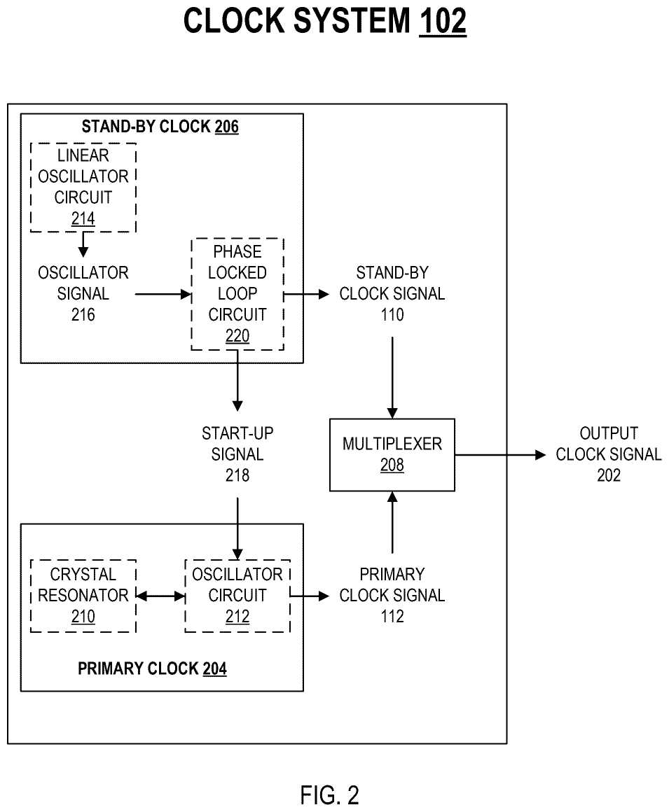

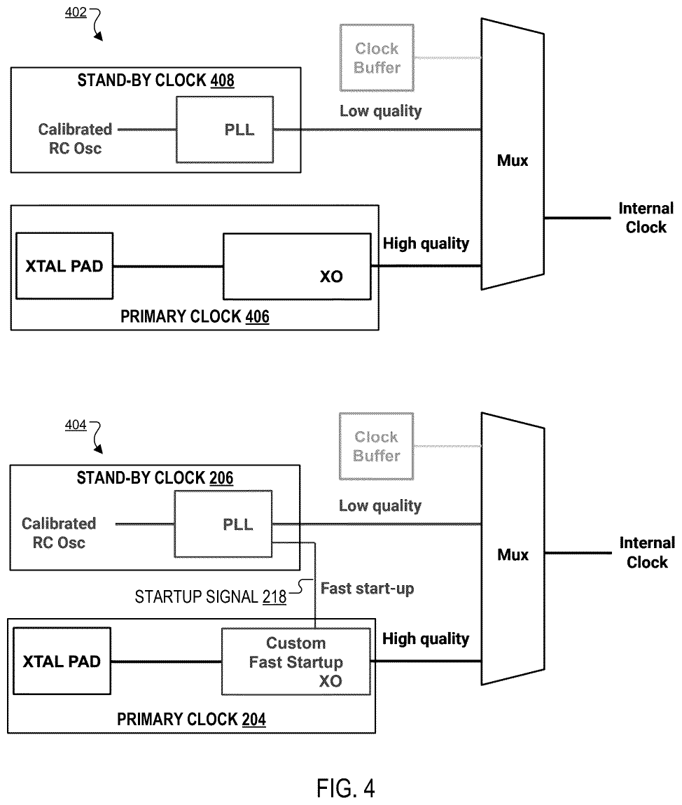

As described in more detail below with reference to FIG. 2, the clock system 102 can reduce the start-up time of the primary clock by providing a start-up signal from the stand-by clock to the primary clock when switching from the low-power mode 106 to the active mode 108. As illustrated in FIG. 4, by reducing the start-up time of the primary clock, the system 102 can remain in the low-power mode for a wider range of situations, which can significantly reduce the average power consumption of the clock circuit.

FIG. 2 is a block diagram for an example clock system 102. As described above, the system 102 can generate an output clock signal 202 while operating in either an active mode or in a low-power mode. When the system 102 operates in the active mode, the output clock signal 202 can be a higher quality primary clock signal 112. When the system 102 operates in the low-power mode, the output clock signal 202 can be a lower quality stand-by signal 110.

The clock system 102 can include a primary clock 204 and a stand-by clock 206. The system 102 can use the primary clock 204 to generate the primary clock signal 112 when the system 102 operates in the active mode. The system 102 can use the stand-by clock 206 to generate the stand-by clock signal 110 when the system 102 operates in the low-power mode.

The clock system 102 can include a multiplexer 208 configured to receive the stand-by clock signal 110 and the primary clock signal 112 and to output the output clock signal 202. When the system 102 operates in the low-power mode, the multiplexer 208 can output the stand-by clock signal 110 as the output clock signal 202. When the system 102 operates in the active mode, the multiplexer 212 can output the primary clock signal 112 as the output clock signal 202.

The power required by the stand-by clock to produce the stand-by clock signal 110 can be less than the power required by the primary clock to produce the primary clock signal 112. The stand-by clock 206 can require less power to produce the stand-by clock signal 110 than the primary clock 204 requires to produce the primary clock signal 112. For example, the stand-by clock 206 can require less power than the primary clock 204 by producing a lower quality clock signal than the primary clock by, e.g., producing the stand-by clock signal 110 at a lower frequency than the primary clock signal 112, producing the stand-by clock signal 110 with more lenient accuracy tolerances than the primary clock signal, producing the stand-by clock signal 110 with less noise filtering than the primary clock signal 112, and so on.

As an example, to produce a high quality primary clock signal 112, the primary clock 204 can be a crystal oscillator that includes a crystal resonator 210 and an oscillator circuit 212. In general, the crystal resonator 210 has a fundamental resonant frequency. The oscillator circuit 212 can amplify signals from the crystal resonator 210 and send signals to the crystal resonator 210. The crystal oscillator can maintain the steady primary clock signal 112 by using the oscillator circuit 212 to amplify and feed signals generated by the crystal resonator 210 back to the crystal resonator 210. When the crystal oscillator starts up, the oscillator circuit 212 can provide an initial signal to the crystal resonator 210 and continuously amplify and feed back signals generated by the crystal resonator 210 until the crystal resonator 210 reaches a steady state of oscillation.

As another example, to consume less power than the primary clock 204, the stand-by clock 206 can include a linear oscillator circuit 214 that can produce an oscillator signal 216 used to generate the stand-by clock signal 110. As a particular example, the linear oscillator circuit 214 can be an RC circuit, which includes a resistor and a capacitor configured to oscillate at a particular frequency.

The clock system 102 can transition from operating in the active mode to operating in the low-power mode by powering down the primary clock 204 and outputting the stand-by clock signal 110 as the output clock signal 202. The system 102 can transition from operating in the low-power mode to operating in the active mode by starting up the primary clock 204 and outputting the primary clock signal 112 as the output clock signal 212.

The primary clock 204 can have a certain start-up time to begin being able to output the primary clock signal 112 with certain required properties (e.g., properties as required by a device receiving the output clock signal 202). For example, the start-up time of the primary clock 204 can be a delay before primary clock 204 is able to output the primary clock signal 112 with, e.g., a certain voltage accuracy, a certain timing accuracy, a certain noise level, a particular duty cycle, and so on. As a particular example, when the primary clock 204 is a crystal oscillator, the start-up time of the crystal oscillator is based on the time required for the crystal oscillator to energize the crystal resonator 208 (e.g., to bring the crystal resonator 208 to the steady-state of oscillation).

The stand-by clock 206 can produce a start-up signal 218 configured to reduce the start-up time of the primary clock 206 that the clock system 102 can provide to the primary clock 204 as part of switching from the low-power mode to the active mode. For example, the start-up signal 218 can be based on a particular resonant frequency of the primary clock 204 and the primary clock 204 can use the start-up signal 218 to start up. By using a start-up signal 218 that can resonate with the primary clock 204, the system 102 can efficiently reduce the start-up time of the primary clock 204. In particular, by using a start-up signal 218 that can resonate with the primary clock 204, the system 102 can reduce the start-up time of the primary clock 204 without requiring additional power.

As a particular example, when the primary clock 204 is a crystal oscillator, the oscillator circuit 212 of the crystal oscillator can receive the start-up signal 218 and send the start-up signal 218 to the crystal resonator 210 of the crystal oscillator. The start-up signal 218 can reduce the start-up time of the crystal oscillator by having a frequency that is any suitable resonant frequency of the crystal resonator 210. As an example, the start-up signal 218 can oscillate at the fundamental resonant frequency of the crystal resonator 210. As another example, the start-up signal 218 can oscillate at a harmonic resonant frequency (e.g., an integer multiple of the fundamental resonant frequency) of the crystal resonator 210.

An example process for transitioning between operating in the low-power mode to operating in the active mode using the start-up signal 218 is described below with reference to FIG. 4.

In some implementations, the stand-by clock 206 can be configured to produce the start-up signal 218 using the stand-by clock signal 110. As an example, start-up signal 218 can be the stand-by clock signal 110. As a further example, the stand-by clock 206 can be configured to produce the stand-by clock signal 110 at a resonance frequency of the primary clock 204 and can use the stand-by clock signal 110 as the start-up signal 218. As another example, the stand-by clock 206 can be configured to produce the stand-by clock signal 110 with a tunable frequency that can be tuned to a resonant frequency of the primary clock 204 and can use the stand-by clock signal 218 as the start-up signal.

In some implementations, the stand-by clock 206 can also include a phase locked loop circuit 220 that can produce the startup signal 218 and, in some implementations, the stand-by clock signal 110. For example, when the stand-by clock 206 generate the stand-by clock signal 110 using the linear oscillator circuit 214, the phase locked loop circuit 220 can receive the oscillator signal 216 from the linear oscillator circuit 214 to produce the start-up signal 218. In particular, the phase locked loop circuit 220 can multiply the oscillator signal 216 from the linear oscillator circuit 214 to target the particular resonant frequency of the primary clock 204. The phase locked loop circuit 220 can also moderate the phase of the start-up signal 218 to maintain resonance with the primary clock 204.

As one particular example, the primary clock 204 can be a crystal oscillator that has a fundamental resonant frequency f₀ and the stand-by clock 206 can include an RC circuit that produces an oscillator signal 216 having frequency f_{RC} and a phase locked loop circuit 220 that multiplies the frequency of the oscillator signal 218 from the RC circuit by a factor, N, to resonate with the fundamental resonant frequency, f₀, of the crystal oscillator. For example, the output signal from the phase locked loop circuit 220 can have frequency f_{PLL}=Nf_{RC}=f₀. The clock system 102 can use the output signal from the phase locked loop circuit (having frequency f_{PLL}) as the start-up signal 218. The system 102 can use a variety of signals as the stand-by clock signal 110. As an example, the system 102 can output the oscillator signal 216 (having frequency f_{RC}) as the stand-by clock signal 218. As another example, the system 102 can output the output signal from the phase locked loop circuit 220 (having frequency f_{PLL}) as the stand-by clock signal 110.

By using a resonant start-up signal 218 from the stand-by clock 206 as described above, the clock system 102 can reduce the start-up time of the primary clock 204 by a factor of 2-10 times. As explained in more detail below with reference to FIG. 4, by reducing the start-up time of the primary clock 204, the system 102 can remain in the low-power mode for a wider range of situations, which can significantly reduce the average power consumption of the system 102.

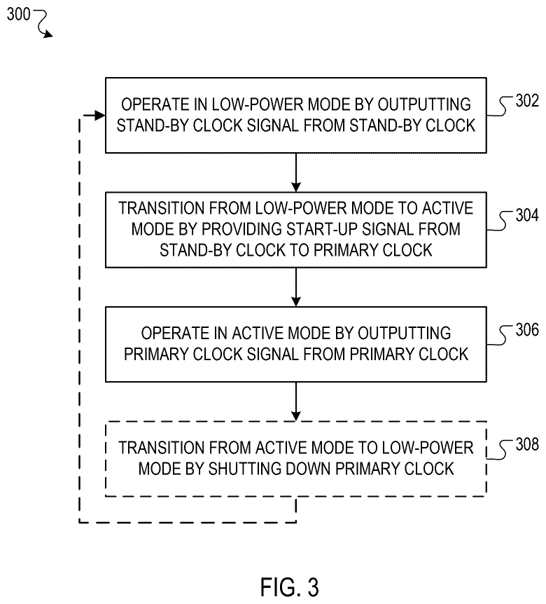

FIG. 3 is a flow diagram of an example process 300 for a clock system to transition between operating in a low-power mode to operating in an active mode. A clock system, such as the clock system 102 of FIG. 1. appropriately configured in accordance with this specification, can perform the process 200.

As described above, the system can include a stand-by clock configured to produce a stand-by clock signal for the system and a primary clock configured to produce a primary clock signal for the system. The stand-by clock can require less power to produce the stand-by clock signal than the primary clock requires to produce the primary clock signal.

For example, the stand-by clock can produce the stand-by clock signal using a linear oscillator circuit (e.g., an RC oscillator) configured to produce an oscillator signal. As another example, the primary clock can produce the primary clock signal using a crystal oscillator. The crystal oscillator can include a crystal resonator that has a fundamental resonant frequency and an oscillator circuit. The oscillator circuit can be configured to amplify signals from the crystal resonator and send (e.g., feed-back) signals to the crystal resonator.

The stand-by clock and the primary clock are described in more detail above with reference to FIG. 2.

While operating in the low-power mode, the system can output the stand-by clock signal from the stand-by clock (step 302). To reduce power consumption in the low-power mode, the primary clock can be powered down (e.g., inactive) while the system operates in the low-power mode.

The system can transition from the low-power mode to the active mode by providing a start-up signal from the stand-by clock to the primary clock (step 304). To transition from the low-power mode to the active mode, the system can start up the primary clock and begin outputting the primary clock signal from the primary clock.

The primary clock can be configured to start up with or without the start-up signal from the stand-by clock. However, starting the primary clock using the start-up signal from the stand-by clock can be faster than starting the primary clock without the start-up signal from the stand-by clock.

As an example, the start-up signal can be based on a particular resonant frequency of the primary clock and the primary clock can be configured to use the start-up signal to start up. As a further example, when the primary clock produces the primary clock signal using a crystal oscillator, the particular resonant frequency of the primary clock can be, e.g., the fundamental resonant frequency of the crystal resonator, a harmonic resonant frequency of the crystal resonator, and so on. As part of starting up the primary clock, the oscillator circuit can receive the start-up signal from the stand-by clock and can send the startup signal to the crystal resonator. By sending a such a resonant start-up signal to the crystal resonator, the system can more quickly energize the crystal resonator to bring the crystal resonator to a steady-state of oscillation for producing the primary clock signal, thereby reducing the start-up time of the primary clock.

The start-up signal is described in more detail above with reference to FIG. 2.

The stand-by clock can produce the start-up signal using the stand-by clock signal. As an example, the start-up signal can be the stand-by clock signal. As another example, the stand-by clock can produce the start-up signal by processing the stand-by clock signal using a circuit (e.g., a phased lock loop circuit) configured to receive the stand-by clock signal. As a particular example, the stand-by clock can include a phase locked loop circuit configured to produce the start-up signal targeting the particular resonant frequency of the primary clock of system. For example, when the stand-by clock generates the stand-by clock signal using a linear oscillator circuit, the phase locked loop circuit can be configured to receive the oscillator signal from the linear oscillator circuit and multiply the frequency of the oscillator signal to produce the start-up signal targeting the particular resonant frequency of the primary clock of system.

Once the system has transitioned to operating in the active mode, the system can output the primary clock signal from the primary clock (step 306).

After a length of time operating in the active mode, the system can, optionally, transition from operating in the active mode to operating in the low-power mode by powering down the primary clock and outputting the stand-by clock signal (step 308). After returning to the low-power mode, the system can output the stand-by clock signal from the stand-by clock.

FIG. 4 illustrates a comparison of power consumption by a conventional clock circuit 402 and a clock circuit 404 configured as described in this specification.

The conventional clock circuit 402 includes as a primary clock 406 a crystal resonator with a crystal oscillator circuit that can output a high quality clock signal. The conventional clock circuit 402 can require a certain amount of energy to power the crystal oscillator circuit and generate the high quality clock signal. Notably, the conventional clock circuit 402 does not use a resonant start-up signal to power up the crystal oscillator.

The conventional clock circuit 402 includes as a stand-by clock 408 an RC circuit with a phase locked loop circuit that can output a lower quality clock signal than the crystal oscillator. To power the RC circuit and the phase locked loop circuit to generate the lower quality clock signal, the conventional clock circuit 402 may require, e.g., 10% of the amount of energy as required to generate the high quality clock signal using the crystal resonator and the crystal oscillator circuit. To reduce power consumption, the conventional clock circuit 402 can enter a low-power mode in which the clock circuit powers down the crystal oscillator circuit and outputs the lower quality clock signal. When needed, the conventional clock circuit 402 can enter an active mode by powering up the crystal oscillator to output the high quality clock signal. However, on its own, the crystal oscillator may have a significant start-up time, before being able to output the high quality clock signal.

The start-up time of the crystal oscillator can significantly limit how often the conventional clock circuit 402 can enter the low-power mode to reduce power consumption. For example, the conventional clock circuit 402 may need to stay in the active mode to provide an appropriate clock signal in anticipation of situations where the device requires the high quality clock signal sooner than the start-up time of the crystal oscillator. As an example, the conventional clock circuit 402 may only be able to enter the low-power mode for 20% of its operation. The conventional clock circuit 402 may only require the high quality clock signal for a small fraction of the remaining 80% of its operation but may need to remain in the active mode powering the crystal oscillator to account for the long start-up time. In this example, the conventional clock circuit 402 can have an average power consumption of 82% of that of the crystal oscillator, with most of the power being consumed to power the crystal oscillator during times when the high quality clock signal is not needed.

In comparison, the clock circuit 404 uses a resonant start-up signal 218 to power up the crystal oscillator. The start-up signal 218 is generated by the RC circuit and the phase locked loop circuit to oscillate at a resonant frequency of the crystal oscillator. As described above with reference to FIG. 2, by using the resonant start-up signal 218 to power up the crystal oscillator, the clock circuit 404 can reduce the start-up time of the crystal oscillator by a factor of 2-10 times.

By reducing the start-up time of the crystal oscillator using the resonant start-up signal 218, the clock circuit 404 can remain in the low-power mode more often than the conventional clock circuit 402. As an example, the clock circuit 404 may only need to enter the active mode during 20% of its operation because of the reduced start-up time. The clock circuit 404 may then be able to remain in the low-power mode for 80% of its operation. In this example, the clock circuit 404 can have an average power consumption of 28% of that of the crystal oscillator.

Therefore, the clock circuit 404, when configured as described by this specification, can use the start-up signal 218 to reduce the start-up time of the crystal oscillator, which can significantly reduce the average power consumption of the clock circuit 404 as compared to both the crystal oscillator and the conventional clock circuit 402.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program which may also be referred to or described as a program, software, a software application, an app, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

As used in this specification, an “engine,” or “software engine,” refers to a software implemented input/output system that provides an output that is different from the input. An engine can be an encoded block of functionality, such as a library, a platform, a software development kit (“SDK”), or an object. Each engine can be implemented on any appropriate type of computing device, e.g., servers, mobile phones, tablet computers, notebook computers, music players, e-book readers, laptop or desktop computers, PDAs, smart phones, or other stationary or portable devices, that includes one or more processors and computer readable media. Additionally, two or more of the engines may be implemented on the same computing device, or on different computing devices.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and pointing device, e.g, a mouse, trackball, or a presence sensitive display or other surface by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone, running a messaging application, and receiving responsive messages from the user in return.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

In addition to the embodiments described above, the following embodiments are also innovative:

Embodiment 1 is a system, comprising:
a stand-by clock, configured to produce a stand-by clock signal when the system is in a low-power mode and to produce a start-up signal when the system switches from the low-power mode to an active mode;
a primary clock, configured to produce a primary clock signal when the system is in the active mode; and
wherein the system is configured to switch from the low-power mode to the active mode by providing the start-up signal from the stand-by clock to the primary clock.
   Embodiment 2 is the system of embodiment 1, wherein the primary clock is configured to start up with or without the start-up signal from the stand-by clock, wherein starting the primary clock using the start-up signal from the stand-by clock is faster than starting the primary clock without the start-up signal from the stand-by clock.
   Embodiment 3 is the system of embodiment 1 or embodiment 2, wherein the stand-by clock produces the start-up signal using the stand-by clock signal.
   Embodiment 4 is the system of embodiment 3, wherein the start-up signal is the stand-by clock signal.
   Embodiment 5 is the system any one of embodiments 1-4, further comprising:
a multiplexer, configured to:
   receive the stand-by clock signal and the primary clock signal;
   output the stand-by clock signal when the system is in the low-power mode; and
   output the primary clock signal when the system is in the active mode;
wherein:
   the start-up signal is based on a particular resonant frequency of the primary clock; and
   the primary clock is configured to use the start-up signal to start up.
      Embodiment 6 is the system of any one of embodiments 1-5, wherein the primary clock comprises:
a crystal resonator, wherein the crystal resonator has a fundamental resonant frequency; and
an oscillator circuit, configured to amplify signals from the crystal resonator and send signals to the crystal resonator.
   Embodiment 7 is the system of embodiment 6, wherein using the start-up signal from the stand-by clock to start up comprises:
receiving, by the oscillator circuit, the start-up signal from the stand-by clock; and
sending the startup signal to the crystal resonator.
   Embodiment 8 is the system of embodiment 6 or embodiment 7, wherein the particular resonant frequency of the primary clock is the fundamental resonant frequency of the crystal resonator.
   Embodiment 9 is the system of embodiment 6 or embodiment 7, wherein the particular resonant frequency of the primary clock is a harmonic resonant frequency of the crystal resonator.
   Embodiment 10 is the system of any one of embodiments 1-9, wherein the stand-by clock comprises:
a linear oscillator circuit, configured to produce an oscillator signal; and
a phase locked loop circuit, configured to:
   receive the oscillator signal from the linear oscillator circuit; and
   multiply the frequency of the oscillator signal to produce the start-up signal targeting the particular resonant frequency of the primary clock.
      Embodiment 11 is the system of embodiment 10, wherein the linear oscillator circuit is an RC oscillator.
      Embodiment 12 is the system of any one of embodiments 1-11, wherein:
the power required by the stand-by clock to produce the stand-by clock signal is less than the power required by the primary clock to produce the primary clock signal.
   Embodiment 13 is the system of any one of embodiments 1-12, wherein the system is configured to transition from the active mode to the low-power mode by:
powering down the primary clock; and
outputting the stand-by clock signal.
   Embodiment 14 is the system of any one of embodiments 1-13, wherein the system is configured to transition from the low-power mode to the active mode by:
starting up the primary clock; and
outputting the primary clock signal.
   Embodiment 15 is a method, comprising:
outputting a stand-by clock signal from a stand-by clock when in a low-power mode;
outputting a primary clock signal from a primary clock when in an active mode; and
transitioning from the low-power mode to the active mode by providing a start-up signal from the stand-by clock to the primary clock.
   Embodiment 16 is the method of embodiment 15, wherein the primary clock is configured to start up with or without the start-up signal from the stand-by clock, wherein starting the primary clock using the start-up signal from the stand-by clock is faster than starting the primary clock without the start-up signal from the stand-by clock.
   Embodiment 17 is the method of embodiment 15 or embodiment 16, wherein the stand-by clock produces the start-up signal using the stand-by clock signal.
   Embodiment 18 is the method of embodiment 17, wherein the start-up signal is the stand-by clock signal.
   Embodiment 19 is the method of any one of embodiments 15-18, wherein:
the start-up signal is based on a particular resonant frequency of the primary clock; and
the primary clock is configured to use the start-up signal to start up.
   Embodiment 20 is the method of any one of embodiments 15-19, wherein the primary clock comprises:
a crystal resonator, wherein the crystal resonator has a fundamental resonant frequency; and
an oscillator circuit, configured to amplify signals from the crystal resonator and send signals to the crystal resonator.
   Embodiment 21 is the method of embodiment 20, wherein using the start-up signal from the stand-by clock to start up comprises:
receiving, by the oscillator circuit, the start-up signal from the stand-by clock; and
sending the startup signal to the crystal resonator.
   Embodiment 22 is the method of embodiment 20 or embodiment 21, wherein the particular resonant frequency of the primary clock is the fundamental resonant frequency of the crystal resonator.
   Embodiment 23 is the method of embodiment 20 or embodiment 21, wherein the particular resonant frequency of the primary clock is a harmonic resonant frequency of the crystal resonator.
   Embodiment 24 is the method of any one of embodiments 15-23, wherein the stand-by clock comprises:
a linear oscillator circuit, configured to produce an oscillator signal; and
a phase locked loop circuit, configured to:
   receive the oscillator signal from the linear oscillator circuit; and
   multiply the frequency of the oscillator signal to produce the start-up signal targeting the particular resonant frequency of the primary clock.
      Embodiment 25 is the method of embodiment 24, wherein the linear oscillator circuit is an RC oscillator.
      Embodiment 26 is the method of any one of embodiments 15-25, wherein:
the power required by the stand-by clock to produce the stand-by clock signal is less than the power required by the primary clock to produce the primary clock signal.
   Embodiment 27 is the method of any one of embodiments 15-26, further comprising transitioning from the active mode to the low-power mode by:
powering down the primary clock; and
outputting the stand-by clock signal.
   Embodiment 28 is the method of any one of embodiments 15-27, wherein transitioning from the low-power mode to the active mode further comprises:
starting up the primary clock; and
outputting the primary clock signal.
   Embodiment 29 is a computer storage medium encoded with instructions that are operable, when executed by data processing apparatus, to cause the data processing apparatus to perform operations comprising the method of any one of embodiments 15-28.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

1. A system, comprising:
a stand-by clock, configured to produce a stand-by clock signal when the system is in a low-power mode and to produce a start-up signal when the system switches from the low-power mode to an active mode;
a primary clock, configured to produce a primary clock signal when the system is in the active mode; and
wherein the system is configured to switch from the low-power mode to the active mode by providing the start-up signal from the stand-by clock to the primary clock.

2. The system of claim 1, wherein the primary clock is configured to start up with or without the start-up signal from the stand-by clock, wherein starting the primary clock using the start-up signal from the stand-by clock is faster than starting the primary clock without the start-up signal from the stand-by clock.

3. The system of claim 1, wherein the stand-by clock produces the start-up signal using the stand-by clock signal.

4. The system of claim 3, wherein the start-up signal is the stand-by clock signal.

5. The system of claim 1, further comprising:
a multiplexer, configured to:
receive the stand-by clock signal and the primary clock signal;
output the stand-by clock signal when the system is in the low-power mode; and
output the primary clock signal when the system is in the active mode;
wherein:
the start-up signal is based on a particular resonant frequency of the primary clock; and
the primary clock is configured to use the start-up signal to start up.

6. The system of claim 1, wherein the primary clock comprises:
a crystal resonator, wherein the crystal resonator has a fundamental resonant frequency; and
an oscillator circuit, configured to amplify signals from the crystal resonator and send signals to the crystal resonator.

7. The system of claim 6, wherein using the start-up signal from the stand-by clock to start up comprises:
receiving, by the oscillator circuit, the start-up signal from the stand-by clock; and
sending the startup signal to the crystal resonator.

8. The system of claim 6, wherein the particular resonant frequency of the primary clock is the fundamental resonant frequency of the crystal resonator.

9. The system of claim 1, wherein the stand-by clock comprises:
a linear oscillator circuit, configured to produce an oscillator signal; and
a phase locked loop circuit, configured to:
receive the oscillator signal from the linear oscillator circuit; and
multiply the frequency of the oscillator signal to produce the start-up signal targeting the particular resonant frequency of the primary clock.

10. The system of claim 1, wherein:
the power required by the stand-by clock to produce the stand-by clock signal is less than the power required by the primary clock to produce the primary clock signal.

11. A method, comprising:
outputting a stand-by clock signal from a stand-by clock when in a low-power mode;
outputting a primary clock signal from a primary clock when in an active mode; and
transitioning from the low-power mode to the active mode by providing a start-up signal from the stand-by clock to the primary clock.

12. The method of claim 11, wherein the primary clock is configured to start up with or without the start-up signal from the stand-by clock, wherein starting the primary clock using the start-up signal from the stand-by clock is faster than starting the primary clock without the start-up signal from the stand-by clock.

13. The method of claim 11, wherein the stand-by clock produces the start-up signal using the stand-by clock signal.

14. The method of claim 13, wherein the start-up signal is the stand-by clock signal.

15. The method of claim 11, wherein:
the start-up signal is based on a particular resonant frequency of the primary clock; and
the primary clock is configured to use the start-up signal to start up.

16. The method of claim 11, wherein the primary clock comprises:
a crystal resonator, wherein the crystal resonator has a fundamental resonant frequency; and
an oscillator circuit, configured to amplify signals from the crystal resonator and send signals to the crystal resonator.

17. The method of claim 16, wherein using the start-up signal from the stand-by clock to start up comprises:
receiving, by the oscillator circuit, the start-up signal from the stand-by clock; and
sending the startup signal to the crystal resonator.

18. The method of claim 16, wherein the particular resonant frequency of the primary clock is the fundamental resonant frequency of the crystal resonator.

19. The method of claim 11, wherein the stand-by clock comprises:
a linear oscillator circuit, configured to produce an oscillator signal; and
a phase locked loop circuit, configured to:
receive the oscillator signal from the linear oscillator circuit; and
multiply the frequency of the oscillator signal to produce the start-up signal targeting the particular resonant frequency of the primary clock.

20. A computer storage medium encoded with instructions that are operable, when executed by data processing apparatus, to cause the data processing apparatus to perform operations comprising:
outputting a stand-by clock signal from a stand-by clock when in a low-power mode;
outputting a primary clock signal from a primary clock when in an active mode; and
transitioning from the low-power mode to the active mode by providing a start-up signal from the stand-by clock to the primary clock.
